(19) United States
(12) Patent Application Publication
(10) Pub. No.: US 2026/0334125 A1
(43) Pub. Date: Oct. 22, 2026

(54) SYSTEM FOR FUMIGATING A LOAD LOCK OF A SUBSTRATE PROCESSING SYSTEM

(71) Applicant: Lam Research Corporation, Fremont, CA (US)

(72) Inventors: Travis R. TAYLOR, Portland, OR (US); Lawrence Matthew Roberts, Tigard, OR (US); Thor Andreas Raabe, Tampa, FL (US); Geoffrey Hohn, Portland, OR (US)

(21) Appl. No.: 19/146,995

(22) PCT Filed: Jan. 8, 2024
(86) PCT No.: PCT/US2024/010669

§ 371 Date: Jul. 10, 2025

Related U.S. Application Data
(60) Provisional application No. 63/439,887, filed on Jan. 19, 2023.

(51) Int. Cl. H10P 72/00

(52) U.S. Cl. CPC H10P 72/0402

(57) ABSTRACT

A fumigation system includes a fumigating gas generator configured to supply a fumigating gas at a first predetermined flow rate. A fumigating gas delivery system includes a first gas flow path in fluid communication with a node and a destruction unit. A second gas flow path is in fluid communication with the node and a load lock. The fumigating gas delivery system is configured to operate in a first mode during which the second gas flow path is closed, and the first gas flow path delivers the fumigating gas to the destruction unit and a second mode during which the fumigating gas delivery system delivers some of the fumigating gas to the destruction unit and supplies the fumigating gas to the load lock at a second predetermined flow rate that is less than or equal to the first predetermined flow rate.

### CROSS-REFERENCE TO RELATED APPLICATIONS

This application claims the benefit of U.S. Provisional Application No. 63/439,887, filed on Jan. 19, 2023. The entire disclosure of the application referenced above is incorporated herein by reference.

### FIELD

The present disclosure relates to substrate processing systems, and more particularly to a system for fumigating a load lock of a substrate processing system.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

Substrate processing systems may be used to treat substrates such as semiconductor wafers. The substrates are delivered to an equipment front end module (EFEM) of the substrate processing system. The substrates are moved by robots from the EFEM into an inbound load lock and then through a vacuum transfer module to the processing chamber.

The substrate is arranged on a substrate support in the processing chamber. The substrate treatment that is performed in the processing chamber may include deposition, etching, cleaning, and other substrate treatments. A gas delivery system delivers process gases to the processing chamber. Plasma or another treatment may be used to enhance chemical reactions. After processing, the substrate is moved by a robot through the vacuum transfer module to an outbound load lock and then to the EFEM and the process repeats.

### SUMMARY

A fumigation system includes a fumigating gas generator configured to supply a fumigating gas at a first predetermined flow rate. A fumigating gas delivery system includes a first gas flow path in fluid communication with a node and a destruction unit. A second gas flow path is in fluid communication with the node and a load lock. The fumigating gas delivery system is configured to operate in a first mode during which the second gas flow path is closed, and the first gas flow path delivers the fumigating gas to the destruction unit and a second mode during which the fumigating gas delivery system delivers some of the fumigating gas to the destruction unit and supplies the fumigating gas to the load lock at a second predetermined flow rate that is less than or equal to the first predetermined flow rate.

In some examples, the fumigating gas comprises ozone. A first valve and a check valve are connected between the fumigating gas generator and the node. The first gas flow path includes a first valve fluidly connected to the node, a check valve fluidly connected to the first valve, and a second valve fluidly connected between the check valve and the destruction unit.

In other features, the first gas flow path includes a first valve fluidly connected between the node and the destruction unit. The second gas flow path includes a second valve fluidly connected to the node, a mass flow controller (MFC) fluidly connected to the second valve, and a third valve fluidly connected to the MFC.

In other features, a first pressure sensor is configured to sense a first pressure between the second valve and the MFC. A second pressure sensor is configured to sense a second pressure between the third valve and the load lock. A throttle valve and a pump are configured to adjust a pressure in the load lock. A controller is configured to adjust the first valve, the second valve and the throttle valve.

In other features, during the second mode, the controller is configured to monitor a pressure drop across the MFC based on the first pressure and the second pressure and to adjust the first valve, the second valve and the throttle valve to maintain the second predetermined flow rate. The controller is configured to, after a substrate is delivered to the load lock during a first period, supply a soak gas to the load lock during a second period. After the second period, the controller is configured to soak the substrate for a third period. The controller is configured pump down the load lock during a fourth period and fumigate the load lock using the fumigating gas during a fifth period.

In other features, the controller is configured to pump down the load lock during a sixth period and perform one or more partial vent and pump down cycles during seventh and eighth periods. In other features, the controller is configured to equalize pressure in the load lock during a ninth period and transfer the substrate from the load lock during a tenth period.

In other features, the controller is configured to supply a soak gas to the load lock during a first period; after the first period, soak for a second period; pump down the load lock during a third period; and fumigate the load lock using the fumigating gas during a fourth period. The controller is configured to pump down the load lock during a fifth period; perform one or more partial vent and pump down cycles during sixth and seventh periods; and equalize pressure in the load lock during an eighth period.

A method for fumigating a load lock of a substrate processing system includes supplying a fumigating gas at a first predetermined flow rate; providing a first gas flow path in fluid communication with a node and a destruction unit; providing a second gas flow path in fluid communication with the node and a load lock; during a first mode, blocking the second gas flow path and delivering the fumigating gas to the destruction unit via the first gas flow path; and during a second mode, delivering some of the fumigating gas to the destruction unit and supplying the fumigating gas to the load lock at a second predetermined flow rate that is less than or equal to the first predetermined flow rate.

In other features, the fumigating gas comprises ozone. The method includes arranging a first valve and a check valve between a fumigating gas generator and the node. The first gas flow path includes a first valve fluidly connected to the node, a check valve fluidly connected to the first valve, and a second valve fluidly connected between the check valve and the destruction unit.

In other features, the first gas flow path includes a first valve fluidly connected between the node and the destruction unit. The second gas flow path includes a second valve fluidly connected to the node, a mass flow controller (MFC) fluidly connected to the second valve, and a third valve fluidly connected to the MFC.

In other features, the method includes sensing a first pressure between the second valve and the MFC, and sensing a second pressure between the third valve and the load lock. The method includes adjusting a pressure in the load lock using a throttle valve and a pump. The method includes adjusting a pressure drop across the mass flow controller using the first valve, the second valve, and the throttle valve. During the second mode, the method includes monitoring a pressure drop across the MFC based on the first pressure and the second pressure and adjusting the first valve, the second valve and the throttle valve to maintain the second predetermined flow rate.

In other features, after a substrate is delivered to the load lock during a first period, the method includes supplying a soak gas to the load lock during a second period. After the second period, the method includes soaking the substrate for a third period. The method includes pumping down the load lock during a fourth period. The method includes fumigating the load lock using the fumigating gas during a fifth period.

In other features, the method includes pumping down the load lock during a sixth period and performing one or more partial vent and pump down cycles during seventh and eighth periods. The method includes equalizing pressure in the load lock during a ninth period and transferring the substrate from the load lock during a tenth period.

In other features, the method includes supplying a soak gas to the load lock during a first period; after the first period, soaking for a second period; pumping down the load lock during a third period; and fumigating the load lock using the fumigating gas during a fourth period. In other features, the method includes pumping down the load lock during a fifth period; performing one or more partial vent and pump down cycles during sixth and seventh periods; and equalizing pressure in the load lock during an eighth period.

Further areas of applicability of the present disclosure will become apparent from the detailed description, the claims, and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1A is a functional block diagram of an EFEM, a load lock, a vacuum transfer module, and one or more processing chambers;

FIG. 1B is a functional block diagram of an example of a fumigation system according to the present disclosure;

FIG. 1C is a functional block diagram of a control system for a fumigation system according to the present disclosure;

FIG. 2 are graphs illustrating an example of throttle valve position and pressure as a function of time during fumigation according to the present disclosure; and

FIGS. 3A to 3C are functional block diagrams showing gas flow during various operating modes of the fumigation system according to the present disclosure.

In the drawings, reference numbers may be reused to identify similar and/or identical elements.

### DETAILED DESCRIPTION

In some applications, a fumigation system includes a fumigation gas generator that supplies fumigation gas such as ozone to fumigate a processing chamber or other enclosures. For example, fumigation gas may also be supplied to other enclosures such as a load lock (e.g., an inbound load lock or an outbound load lock) with or without a substrate being present. The volumes of the enclosures may vary, which may make a fumigation gas generator oversized for the enclosure with a smaller volume. A custom gas generator is typically designed with a desired flow rate and pressure for supplying the fumigation gas to the outbound load lock. When the forming gas generator is sized to provide the desired flow rate and pressure for the outbound load lock, passive components such as orifices and needle valves are used.

The fumigation gas can also be supplied to the load lock using the same fumigation gas generator that is designed for larger enclosures (e.g., higher flow rates and pressures) required by the larger enclosure (e.g., the processing chamber). However, the processing chambers and the load locks do not have the same volumes and/or the pumps used to evacuate reactants from the processing modules and load locks may not have sufficient capacity to handle the higher gas flow directly from the fumigation gas generator.

The fumigation system according to the present disclosure enables tuning or adjustment to a high-capacity fumigating gas generator's gas supply so that it can deliver fumigating gas to enclosures (e.g., certain load locks) requiring less flow and/or pressure. According to some embodiments, the fumigation system diverts excess fumigation gas as needed to provide a desired flow and/or pressure. The fumigation system according to the present disclosure uses a throttle valve on a vacuum side of the load lock to balance changes in flow of the fumigation gas (and subsequent pressure changes) on the vacuum side. On the supply side of the load lock, the fumigation system uses a pressure-based mass flow controller (MFC) that can be used with the fumigation gas (e.g., ozone) and that can deliver the fumigation gas at less than atmospheric pressure. A controller monitors the pressure drop across the MFC to control the amount of fumigation gas that is diverted and to control a valve located upstream from the MFC to maintain the desired pressure drop across the MFC.

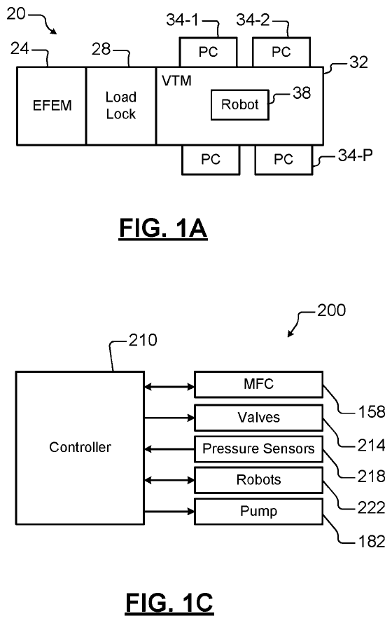

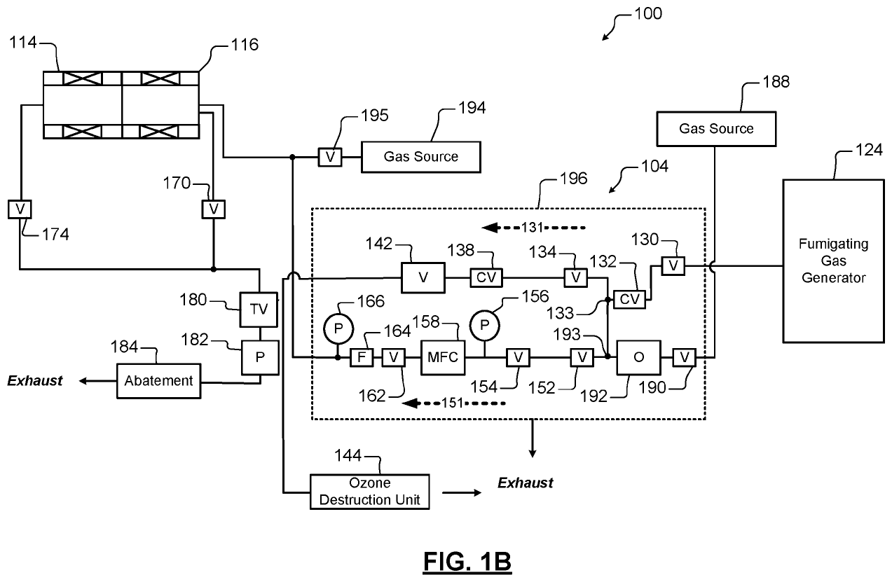

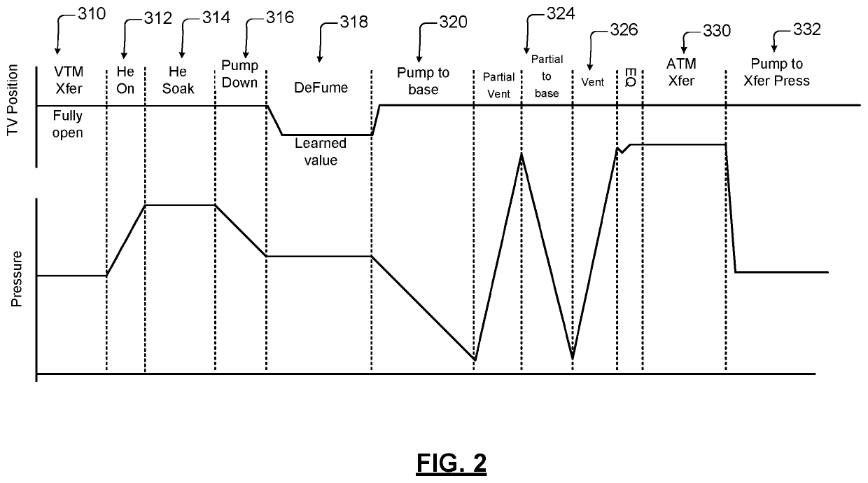

Referring now to FIG. 1A, a substrate processing system 20 includes an equipment front end module (EFEM) 24, a load lock 28, a vacuum transfer module (VTM) 32, and one or more processing chamber 34-1, 34-2, ..., and 34-P (collectively or individually processing chamber 34), where P is an integer greater than zero. A load lock includes an inbound load lock and an outbound load lock shown below. In the foregoing description, the fumigation system will be described fumigating the outbound load lock with a substrate present. However, the fumigation system can be used to fumigate the inbound load lock and/or another processing volume. In addition, the fumigation system can be performed with or without the substrate being present.

Referring now to FIG. 1B, a fumigation system 100 includes a fumigating gas delivery system 104 that selectively delivers fumigating gas to fumigate an enclosure such as an inbound load lock 114 and/or an outbound load lock 116. In this example, the fumigation system 100 is configured to fumigate the outbound load lock 116 using a fumigating gas such as ozone (O₃) or a mixture of ozone and molecular oxygen (O₂). As can be appreciated, however, the fumigation system 100 can be used to fumigate other types of enclosures such as one of the processing chambers. Fumigation of the outbound load lock 116 is performed under certain conditions such as when a substrate is delivered to the outbound load lock 116 after the substrate is processed in one of the processing chambers 34.

The fumigating gas delivery system 104 includes a fumigating gas generator 124 that is configured to supply the fumigating gas at a flow rate that is higher than a flow rate that is needed to fumigate the outbound load lock 116. For example, the fumigating gas generator 124 supplies ozone at a predetermined pressure (e.g., 35 psi) and a fixed flow rate and/or a variable flow rate (e.g., 2 to 9 standard liters per minute (sim)) and pressure. In some examples, the fumigating gas generator 124 supplies flow rates and pressures that are larger than a flow rate and pressure needed for the outbound load lock. The fumigation system 100 is configured to control the flow rate and pressure of the fumigating gas supplied to the outbound load lock and to divert the rest of the fumigating gas from the fumigating gas generator to a destruction unit.

As will be described further below, the fumigation system 100 sends all of the fumigating gas to a first gas flow path (e.g., gas is diverted to a gas destruction unit 144) or splits an output of the fumigating gas generator 124 between the first gas flow path and a second gas flow path (e.g., the outbound load lock 116). The fumigating gas is supplied to the outbound load lock 116 at a predetermined flow rate less than the supplied flow rate of the fumigating gas generator 124.

An output of the fumigating gas generator 124 is fed to a valve 130 and a check valve 132. The check valve 132 prevents backflow towards the fumigating gas generator 124. An output of the check valve 132 is split at a node 133 into two gas flow paths. A first gas flow path 131 corresponds to the flow path for diverted fumigating gas. The first gas flow path 131 is fluidly connected to an inlet of a valve 134, a check valve 138, and a valve 142. An outlet of the valve 142 is fluidly connected to the gas destruction unit 144. The check valve 138 prevents backflow from the gas destruction unit 144.

A second gas flow path 151 selectively supplies fumigating gas to the outbound load lock 116 at a predetermined flow rate. The second gas flow path 151 includes a valve 152, a valve 154, a mass flow controller (MFC) 158, and a valve 162 that meter the flow of the fumigating gas to the outbound load lock 116. A pressure sensor 156 senses pressure at an inlet of the MFC 158. A pressure sensor 166 senses pressure at an outlet of the MFC 158. A filter 164 filters gas output by the valve 162.

The outbound load lock 116 is connected by a valve 170 to a throttle valve 180 and a pump 182 connected to an abatement system 184. The inbound load lock 114 is connected by a valve 174 to the throttle valve 180 and the pump 182 connected to the abatement system 184. Purge gas such as molecular nitrogen (N₂) is selectively supplied by a gas source 188, a valve 190 and an orifice 192 to a node 193 in fluid communication with the node 133 and the valves 134 and 152.

A vent gas source 194 and valve 195 selectively supply gas such as helium (He) or molecular nitrogen (N₂) to the outbound load lock 116. An enclosure 196 surrounds components of the fumigation system 100 and is connected to an exhaust system.

Referring now to FIG. 1C, a control system 200 for the fumigation system 100 is shown. The control system 200 includes a controller 210 configured to control the fumigating process described herein. The controller 210 is configured to directly or indirectly control the MFC 158, valves 214 (such as the valve 142, the valve 154, and the throttle valve 180), pressure sensors 218 (e.g., pressure sensors 156 and 166), robots 222, and the pump 182.

During supply of the fumigation gas to the outbound load lock, the controller 210 monitors pressures measured by the pressure sensors 156 and 166, respectively. The controller 210 adjusts a position of the valve 142 to maintain a predetermined pressure drop (Ap) across the MFC 158. The controller 210 also controls the valve 154 to fine tune Ap across the MFC 158. When fumigating gas is not needed, the controller 210 closes the valve 154 and the fumigating gas is diverted via the first gas flow path 131 to the gas destruction unit 144. The controller 210 also controls a position of the throttle valve 180 to balance vacuum throughput with the O₃ inlet. In some examples, a learned value of the throttle valve position is stored after fumigation is performed and the stored throttle valve position is used as an initial value for the next fumigation cycle.

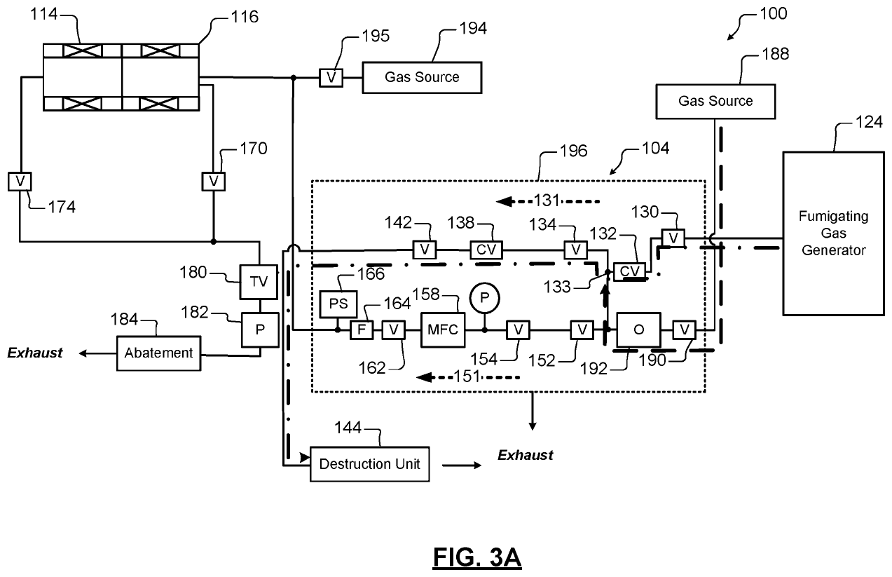

Referring now to FIG. 2, a position of the throttle valve 180 and pressure in the outbound load lock 116 is shown as a function of time. At 310, the throttle valve 180 is initially open and pressure within the outbound load lock 116 is at a vacuum transfer pressure (e.g., 550 mT) corresponding to a pressure within the vacuum transfer module 32. A robot 38 of FIG. 1 delivers the substrate from one of the processing chambers 34 through the vacuum transfer module 32 to the outbound load lock 116.

The outbound load lock 116 is isolated from the vacuum transfer module 32 and a soak gas such as helium (He) or molecular nitrogen (N₂) is supplied to the outbound load lock 116 for a second period 312. The soak gas increases the pressure in the outbound load lock 116 during the second period 312 to a second pressure greater than the first pressure (e.g., such as 200 T). The substrate is soaked during a third period 314 to allow the substrate to cool. After the third period 314, the outbound load lock 116 is pumped down during a fourth period 316 until the pressure is equal to a third pressure (e.g., a pressure less than the second pressure and greater than the first pressure).

During a fifth period 318, the fumigating gas is supplied to the outbound load lock 116 and the throttle valve 180 moves to a partially open position to maintain the third pressure in the outbound load lock 116. In other words, the position of the throttle valve 180 is balanced or adjusted to compensate for fumigating gas supplied to the outbound load lock 116. After the fifth period 318, the supply of the fumigating gas is stopped, the throttle valve 180 is opened, and the outbound load lock 116 is pumped to base pressure (e.g., 100 mT) during a sixth period 320.

During a seventh period 324 and an eighth period 326, a pump/vent cycle is performed one or more times. During the pump/vent cycle, the outbound load lock 116 is partially vented and then pumped to base pressure one or more times. During a ninth period 330 after the pump/vent cycle, the outbound load lock 116 is vented to atmospheric pressure and the substrate is removed. The enclosure is pumped to the vacuum transfer pressure and the process repeats.

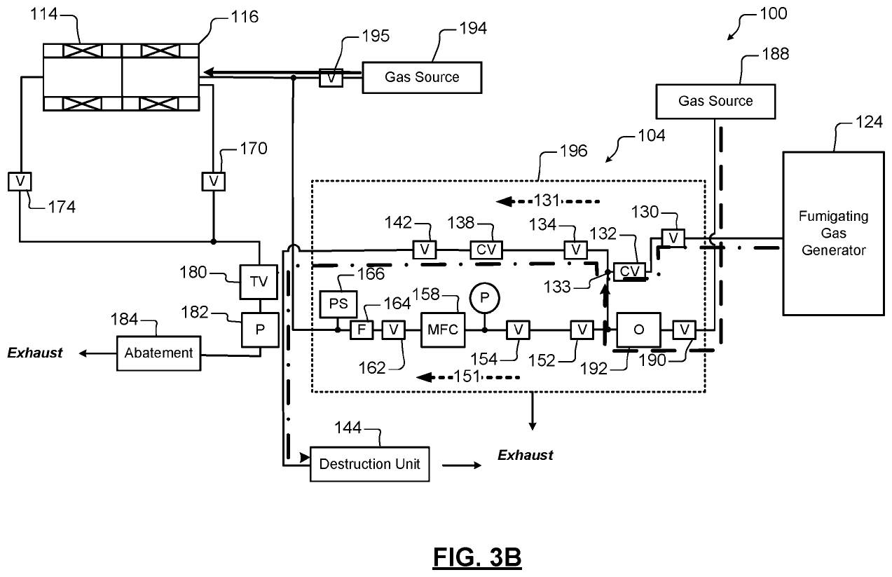

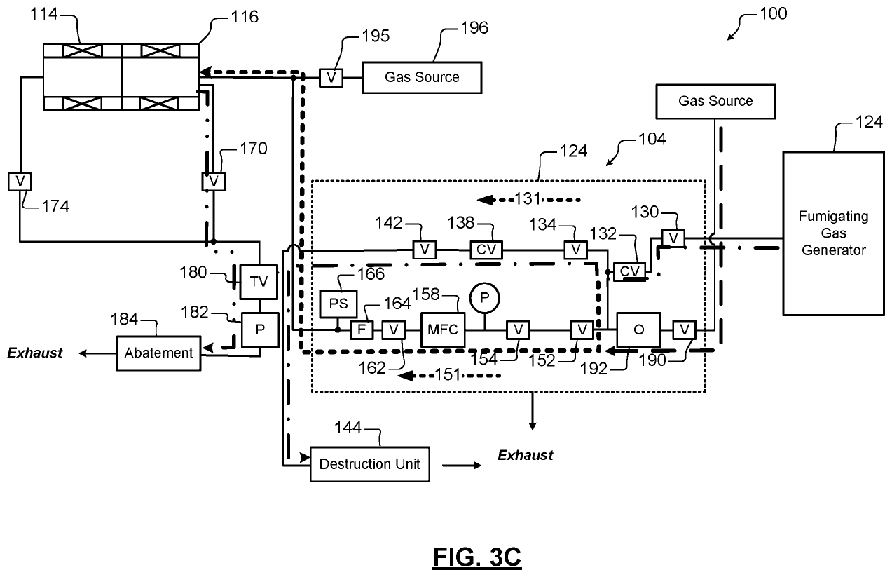

Referring now to FIGS. 3A to 3C, gas flow is shown at different stages. In FIG. 3A, the fumigation system 100 is shown in a standby mode with the fumigating gas diverted to the gas destruction unit 144 and the fumigating gas (e.g., ozone) is not supplied to the outbound load lock 116. In FIG. 3B, the fumigation system 100 is shown during the second period 312 during which the soaking gas is supplied to the outbound load lock 116 after the substrate has been delivered from the processing chamber through the vacuum transfer module after treatment.

In FIG. 3C, the fumigation system 100 is shown during the fifth period 318 while the fumigating gas is supplied to the outbound load lock 116. Some the fumigating gas is diverted to the gas destruction unit 144 via the first gas flow path 131 and the fumigating gas is supplied at a predetermined flow rate via the second gas flow path 151 to the outbound load lock 116. The flow of the fumigating gas is modulated by the controller 210 by monitoring the pressure drop Δp across the MFC 158 and varying positions of the valves 142 and 154 and the throttle valve 180 as described above.

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In some implementations, a controller is part of a system, which may be part of the above-described examples. Such systems can comprise semiconductor processing equipment, including a processing tool or tools, chamber or chambers, a platform, or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with the system, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g., a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus, as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

What is claimed is:

1. A fumigation system comprising:
a fumigating gas generator configured to supply a fumigating gas at a first predetermined flow rate; and
a fumigating gas delivery system including:
a first gas flow path in fluid communication with a node and a destruction unit; and
a second gas flow path in fluid communication with the node and an enclosure,
wherein the fumigating gas delivery system is configured to operate in:
a first mode during which the second gas flow path is closed, and the first gas flow path delivers the fumigating gas to the destruction unit; and
a second mode during which the fumigating gas delivery system delivers some of the fumigating gas to the destruction unit and supplies some of the fumigating gas to the enclosure at a second predetermined flow rate that is less than or equal to the first predetermined flow rate.

2. The fumigation system of claim 1, wherein the fumigating gas comprises ozone.

3. The fumigation system of claim 1, further comprising a first valve and a check valve connected between the fumigating gas generator and the node.

4. The fumigation system of claim 1, wherein the first gas flow path includes:
a first valve fluidly connected to the node;
a check valve fluidly connected to the first valve; and
a second valve fluidly connected between the check valve and the destruction unit.

5. The fumigation system of claim 1, wherein the first gas flow path includes a first valve fluidly connected between the node and the destruction unit.

6. The fumigation system of claim 5, wherein the second gas flow path includes:
a second valve fluidly connected to the node;
a mass flow controller (MFC) fluidly connected to the second valve; and
a third valve fluidly connected to the MFC.

7. The fumigation system of claim 6, further comprising:
a first pressure sensor configured to sense a first pressure between the second valve and the MFC; and
a second pressure sensor configured to sense a second pressure between the third valve and the enclosure.

8. The fumigation system of claim 7, further comprising a throttle valve and a pump configured to adjust a pressure in the enclosure.

9. The fumigation system of claim 8, further comprising a controller configured to adjust the first valve, the second valve and the throttle valve.

10. The fumigation system of claim 9, wherein, during the second mode, the controller is configured to monitor a pressure drop across the MFC based on the first pressure and the second pressure and to adjust the first valve, the second valve and the throttle valve to maintain the second predetermined flow rate.

11. The fumigation system of claim 9, wherein the controller is configured to:
after a substrate is delivered to the enclosure during a first period, supply a soak gas to the enclosure during a second period;
after the second period, soak the substrate for a third period;
pump down the enclosure during a fourth period; and
fumigate the enclosure using the fumigating gas during a fifth period.

12. The fumigation system of claim 11, wherein the controller is configured to:
pump down the enclosure during a sixth period; and
perform one or more partial vent and pump down cycles during seventh and eighth periods.

13. The fumigation system of claim 12, wherein the controller is configured to:
equalize pressure in the enclosure during a ninth period; and
transfer the substrate from the enclosure during a tenth period.

14. The fumigation system of claim 9, wherein the controller is configured to:
supply a soak gas to the enclosure during a first period;
after the first period, soak for a second period;
pump down the enclosure during a third period; and
fumigate the enclosure using the fumigating gas during a fourth period.

15. The fumigation system of claim 14, wherein the controller is configured to:
pump down the enclosure during a fifth period;
perform one or more partial vent and pump down cycles during sixth and seventh periods; and
equalize pressure in the enclosure during an eighth period.

16. The fumigation system of claim 1, wherein the enclosure comprises an inbound load lock.

17. The fumigation system of claim 1, wherein the enclosure comprises an outbound load lock.

18. A method for controlling fumigating gas delivery in a substrate processing system, comprising:
activating a first gas delivery mode of a fumigation system of the substrate processing system;
during the first gas delivery mode, delivering a fumigating gas to a destruction unit via a first gas flow path and blocking a second gas flow path connected to an enclosure;
deactivating the first gas delivery mode; and
activating a second gas delivery mode of the fumigation system of the substrate processing system;
during the second gas delivery mode, delivering some of the fumigating gas to the destruction unit via the first gas flow path while supplying some of the fumigating gas to the enclosure via the second gas flow path.

19-34. (canceled)

35. A fumigation system comprising:
a fumigating gas generator configured to supply a fumigating gas at a first predetermined flow rate; and
a fumigating gas delivery system including:
a first gas flow path in fluid communication with a node and a destruction unit;
a first valve arranged in the first gas flow path;
a second gas flow path in fluid communication with the node and an enclosure;
a second valve arranged in the second gas flow path configured to supply the fumigating gas at a second predetermined flow rate less than the first predetermined flow rate;
a mass flow controller arranged in the second gas flow path;
a pressure sensor configured to sense a pressure drop across the mass flow controller;
a throttle valve and a pump configured to evacuated reactants from the enclosure; and
a controller configured to:
during a fumigation period,
control the first valve to provide a predetermined pressure drop across the mass flow controller; and
control the second valve to provide the second predetermined flow rate.

36-39. (canceled)
